(19) United States
(12) Patent Application Publication
(10) Pub. No.: US 2023/0274994 A1
(43) Pub. Date: Aug. 31, 2023

(54) POWER ELECTRONICS MODULE, ELECTRICAL SYSTEM HAVING SUCH A MODULE, CORRESPONDING MANUFACTURING METHODS

(71) Applicant: VALEO EAUTOMOTIVE FRANCE SAS, Cergy (FR)

(72) Inventor: Aurelien POUILLY, Cergy (FR)

(73) Assignee: VALEO EAUTOMOTIVE FRANCE SAS, Cergy (FR)

(21) Appl. No.: 18/005,021

(22) PCT Filed: Jun. 23, 2021
(86) PCT No.: PCT/EP2021/067106

§ 371 Date: Jan. 10, 2023

(30) Foreign Application Priority Data
Jul. 10, 2020 (FR) FR2007367

(51) Int. Cl. H01L 23/31; H01L 25/07; H05K 1/18; H01L 21/56

(52) U.S. Cl. CPC H01L 23/3121; H01L 25/072; H05K 1/18; H01L 21/56; H05K 2201/10166; H05K 2201/10568; H05K 2201/10901

(57) ABSTRACT

A power electronics module having at least one electronic chip, and an electrically insulating overmolded block at least partially encapsulating each of the at least one chip. The module includes at least one projection against which a component can bear, such as an electronic circuit board for controlling each chip. The projection includes an electrically insulating material and extending from one face of the block.

The present invention relates to a power electronics module, to an electrical system having such a module, and to corresponding manufacturing methods. The invention is applicable in particular to the automotive field.

In numerous industrial applications, power electronics modules having electronic chips are implemented in order to control electrical signals for managing the operation of an electrical system, such as a rotary electric machine.

To protect the chips, it is known to dispose them at the bottom of a plastic casing and to embed them in an electrically insulating gel poured in the casing. Pads provided with fixing orifices can then be provided in lateral walls of the casing. The circuit board then bears against these pads and can be fixed there by means of screws.

Such a solution has a significant drawback, notably because of the use of the casing.

As an alternative, the chips can be protected by an overmolding, for example made of epoxy resin, forming a rigid block which encapsulates the chips. In this case, metal inserts can be provided in the overmolded block to enable the passage of screws for fixing the circuit board. The inserts are, for example, overmolded at the same time as the chips and are flush with a face of the overmolded block facing the circuit board.

In this solution, the circuit board is positioned against the face of the overmolded block and fixed by means of screws screwed in the inserts. Moreover, the presence of the inserts constitutes an extra cost. However, these inserts are indispensable for avoiding the situation in which the screwing causes the overmolded block to crack and compromises the protection of the chips.

Thus, there is no simple solution making it possible to position the circuit board (or any other desired component) at a distance from the overmolded block encapsulating the chips.

It may thus be desirable to provide a power electronics module which makes it possible to alleviate at least some of the aforementioned problems and constraints.

Therefore, what is proposed is a power electronics module having:
at least one electronic chip; and
an electrically insulating overmolded block at least partially encapsulating each chip;
   wherein it comprises at least one projection against which a component can bear, such as an electronic circuit board for controlling each chip, the projection comprising an electrically insulating material and extending from one face of the block.

Thus, by virtue of the one or more projections, it is possible to keep the component at a distance from the block without requiring a plastic casing. Moreover, one or more of these projections may be used to fix the component by screwing without needing a metal insert. This is because the screwing can be done in the material of the projection, such that the screw does not reach the block and there is thus very little risk of damaging the latter.

Optionally, the projection has a free end defining a contact face of the component.

Also optionally, the contact face is planar.

Also optionally, at least one projection is designed to fix the component in place.

Also optionally, the contact face of the projection designed to fix the component in place has a screw hole.

Also optionally, the screw hole is either tapped, or smooth and intended to interact with a thread-forming or self-tapping screw.

Also optionally, the contact face of the projection is designed to allow the component to move away from this contact face.

Also optionally, the contact face of the projection designed to allow the component to move away does not have a bore.

Also optionally, the projection has the form of a cone frustum and/or a truncated pyramid.

Also optionally, the projection and the block are made in one piece.

Also optionally, the projection and the block are formed in two separate parts.

Also optionally, it comprises an electrical conductor, and the projection is fixed to the conductor.

Also optionally, the conductor has an aperture and the projection is fixed to the conductor through the aperture.

Also optionally, the projection is fixed to the conductor by riveting or rivet-heading or overmolding.

Also optionally, the block encapsulates a base of the projection.

What is also proposed is an electrical system having a module according to the invention and a component bearing against each projection.

What is also proposed is a method for manufacturing a module according to the invention, having the following steps:
obtaining the one or more chips;
overmolding the block over the chips, for example by transfer molding or by compression molding; and
producing each projection against which the component can bear.

Optionally, the overmolding step is performed by using a mold having a main molding cavity corresponding to the block and at least one secondary molding cavity respectively corresponding to the one or more projections, this secondary cavity being in communication with the main cavity, such that each projection and the block are in one piece.

Also optionally, the production of each projection is separate from the overmolding step, such that the one or more projections and the block are separate parts.

What is also proposed is a method for manufacturing an electrical system according to the invention, having the following steps:
manufacturing a module according to the invention;
using a machine tool to move the component towards the face of the block until the component bears against each projection;
using the machine tool to detect an increase in a reaction to the movement; and
using the machine tool to stop the movement of the component.

The invention will be better understood from the following description, which is provided solely by way of example with reference to the appended drawings, in which:

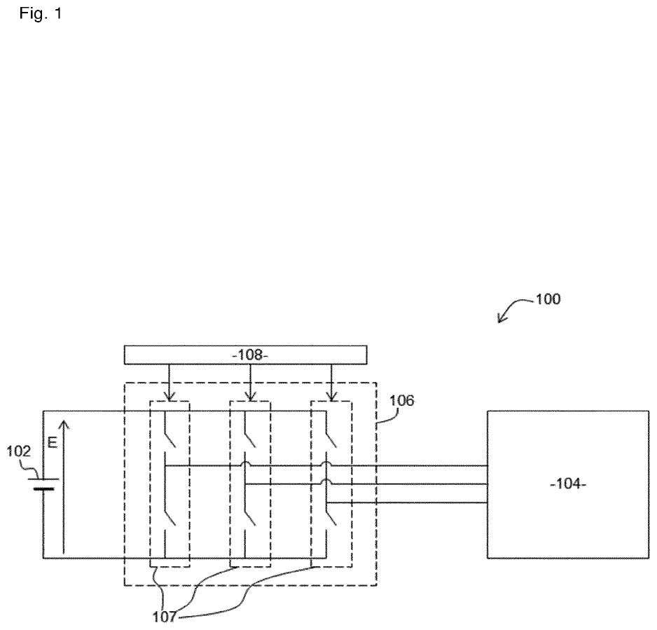

FIG. 1 is a circuit diagram of an exemplary electrical system implementing the invention,

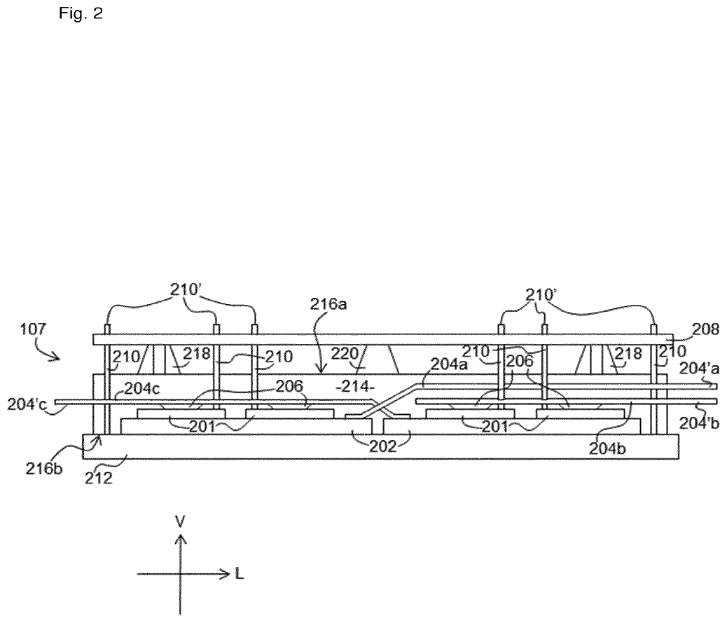

FIG. 2 is a view in section of a power electronics module of the system of FIG. 1,

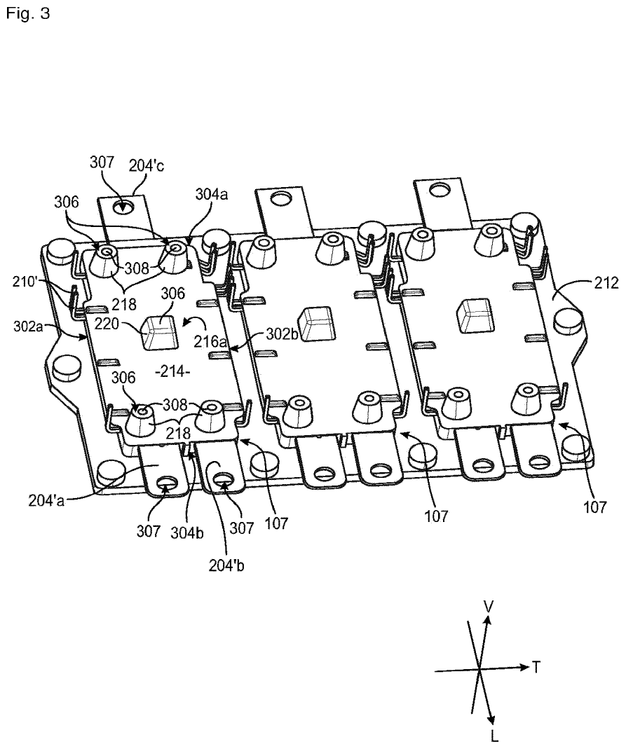

FIG. 3 is a perspective view of a first example of the power electronics module of FIG. 2,

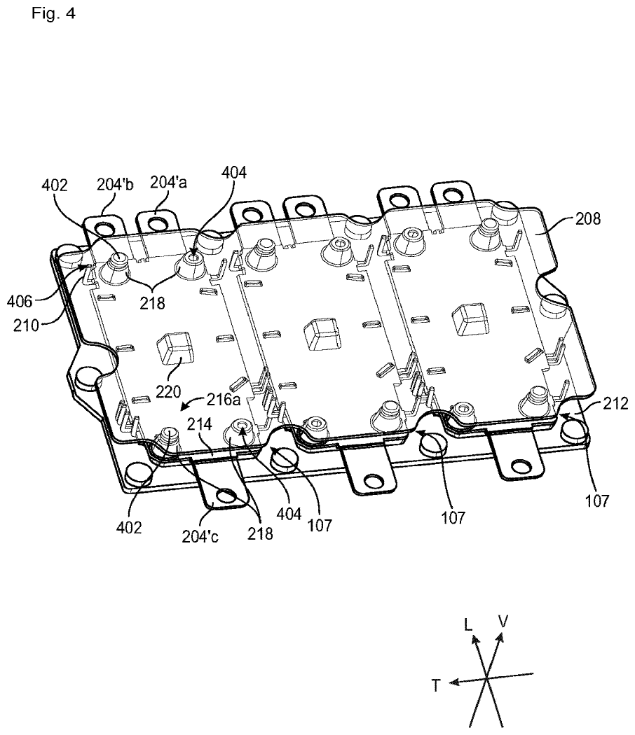

FIG. 4 illustrates the module of FIG. 3, also equipped with an electronic circuit board shown so as to be able to see the rest of the module by transparency,

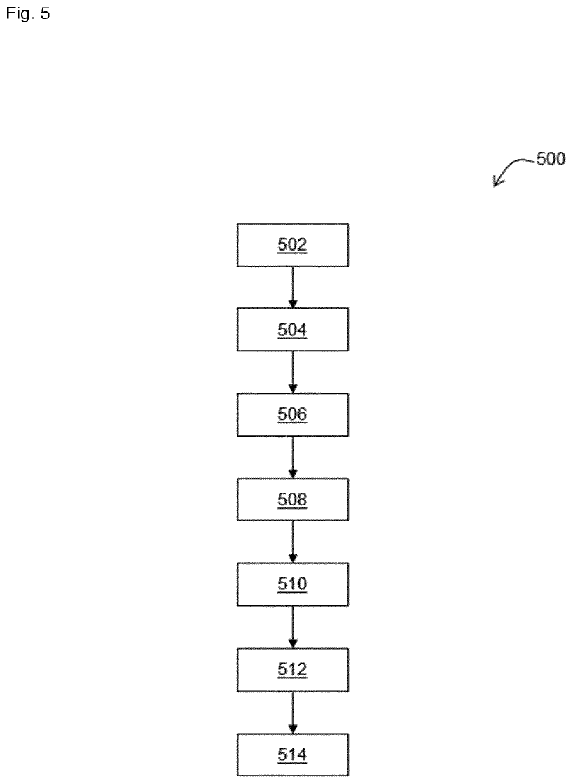

FIG. 5 is a block diagram illustrating the steps of a method for manufacturing an electrical system having the module of FIGS. 2 to 4,

FIG. 5 illustrates, in a partially perspective view, another example of a power electronics module according to the invention,

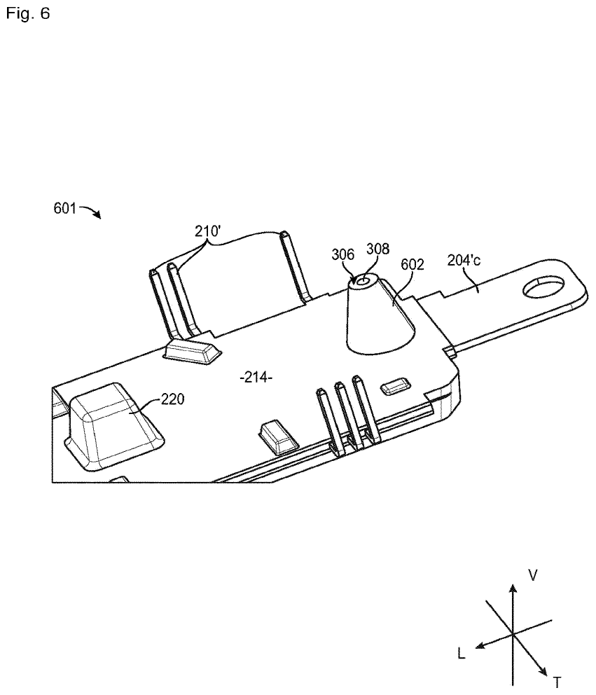

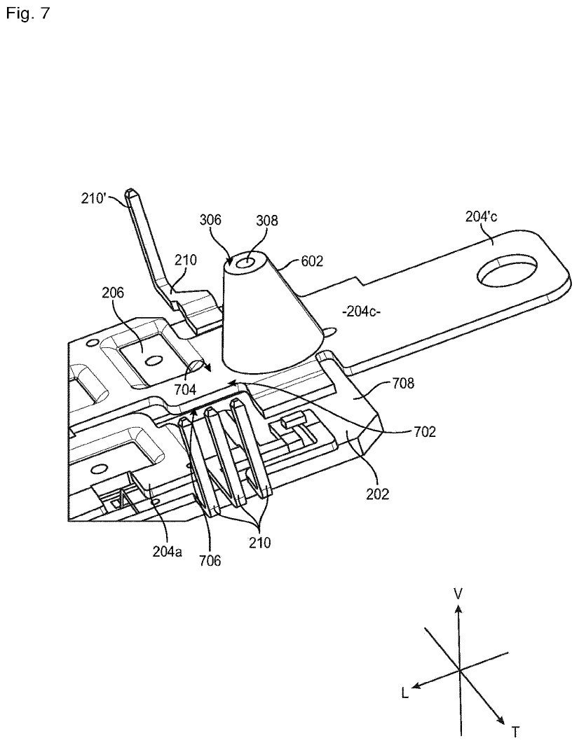

FIG. 7 shows FIG. 6 with an overmolded block of the module removed, and

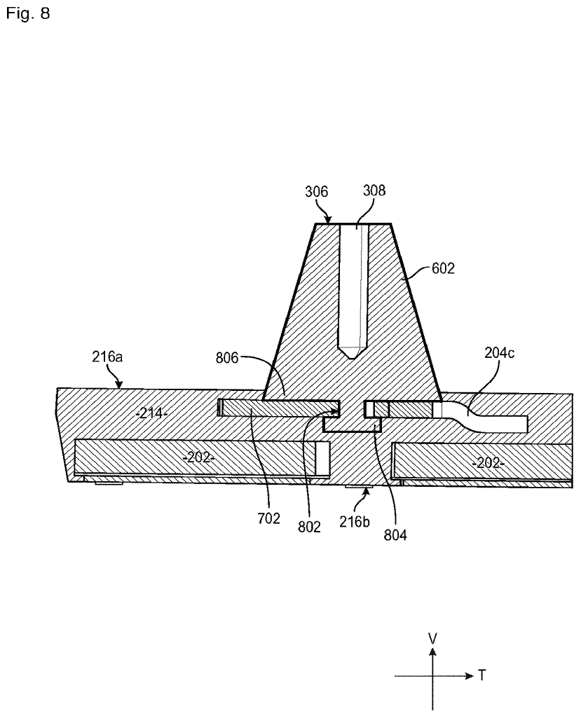

FIG. 8 illustrates a view in section of the module of FIGS. 6 and 7.

An exemplary electrical system 100 implementing the invention will now be described with reference to FIG. 1. The electrical system 100 is intended for example to be implemented in a motor vehicle (not shown).

The electrical system 100 first of all has a DC voltage source 102 having a positive terminal and a negative terminal, the latter generally being connected to an electrical ground, such as a chassis of the motor vehicle. The DC voltage source 102 is designed to supply an input voltage, denoted E.

The electrical system 100 moreover has a rotary electric machine 104 having stator phases. In the example described, the rotary electric machine 104 forms part of a starter-alternator coupled to a combustion engine (not shown) of the motor vehicle. The rotary electric machine 104 is thus designed to operate alternately in motor mode, in which it assists the combustion engine, and in alternator mode, in which it transforms some of the mechanical energy generated by the combustion engine into electrical energy to recharge the DC voltage source 102.

The electrical system 100 moreover has a voltage converter 106 connected, on the one hand, to the terminals of the DC voltage source 102 and, on the other hand, to the rotary electric machine 104.

The voltage converter 106 has switching arms respectively associated with the stator phases. Each switching arm has a high-side switch connected to the positive terminal of the DC voltage source 102 and a low-side switch connected to the negative terminal of the DC voltage source 102. The high-side switch and the low-side switch are moreover connected to one another at a center tap that is connected to the associated stator phase.

Each switching arm is intended to be controlled so as to switch between two configurations. In the first configuration, referred to as high-side configuration, the high-side switch is closed and the low-side switch is open, such that the input voltage E is applied to the associated stator phase. In the second configuration, referred to as low-side configuration, the high-side switch is open and the low-side switch is closed, such that a zero voltage is applied to the associated stator phase.

The electrical system moreover has power electronics modules 107, respectively implementing the switching arms.

The electrical system 100 moreover has a control device 108 for controlling the modules 107, so as to switch each arm between these two configurations. In the example described, the voltage converter 106 is controlled in inverter mode so as to supply electrical energy to the rotary electric machine 104 when it is desired for the latter to operate in motor mode. Moreover, the voltage converter 106 is controlled in rectifier mode so as to supply electrical energy to the DC voltage source 102 (for example to recharge it) when it is desired for the rotary electric machine 104 to operate in alternator mode.

The switches are semiconductor switches having transistors, for example. The switches are, for example, metal oxide semiconductor field effect transistors (or MOSFETs) or else insulated gate bipolar transistors (or IGBTs).

In the following description, the various elements will be given a spatial frame of reference according to an arbitrary orthogonal frame of reference having a vertical direction V, a longitudinal direction L and a transverse direction T.

With reference to FIG. 2, one of the modules 107 will now be described in more detail, the other modules being similar.

The module 107 first of all has one or more electronic chips 201 each comprising, in the example described, one of the semiconductor switches of the switching arms of the voltage converter 106. In the example described, each chip 201 has two opposite electrical connection faces, one upper one and one lower one, and a control terminal.

The module 107 moreover comprises a substrate 202 on which the chips 201 are mounted. In the example described, the substrate 202 is made in two parts, each bearing one or more of the chips 201.

The substrate 202 is advantageously an electronic substrate, such as for example a metal strip or plate or a printed circuit board comprising electrical tracks for electrically connecting multiple chips 201 to one another and/or for electrically connecting a chip 201 to an electrical conductor, such as those that will be described below. For example, the substrate 202 has a ceramic core coated on one or two of its faces with copper. It is, for example, a direct bonded copper substrate, or DBC substrate. As an alternative, the substrate 202 may have a metal plate, such as an aluminum plate, covered by a dielectric layer, which itself is covered by a copper layer.

In particular, the lower face of each chip 201 is electrically and/or mechanically coupled to the substrate 202, for example to at least one of its electrical tracks. Preferably, the lower faces of each electronic chip are coupled at the same time mechanically and electrically to the substrate 202, preferably by brazing.

The module 107 also comprises electrical conductors 204a-c, which are intended to be set to various electrical potentials. They are electrically connected to the chips 201 depending on the circuit desired, in order to implement a switching arm in the example described. The conductors 204a-c are configured to transport electrical signals to or from at least part of the chips 201.

The conductors 204a-c advantageously have substantially planar lead frames. These frames are, for example, metallic. They extend rectilinearly and/or are shaped and have, if necessary, bends and/or changes in plane depending on the desired topography.

The conductors 204a-c have connection ends 204′a-c for electrically or even mechanically attaching the conductors 204a-c to the rest of the voltage converter 106, for example to busbars connecting the module 107 to the DC voltage source 102 and to the rotary electric machine 104.

In the example described, the conductors 204a-c have two conductors 204a, 204b, the respective connection ends 204′a, 204′b of which are connected to the positive terminal and the negative terminal, respectively, of the DC voltage source 102, and a conductor 204c, the connection end 204′c of which is connected to a respective one of the phases of the rotary electric machine 104.

Advantageously, each connection end 204′a-c comprises a through-opening 307 (visible in FIGS. 3 and 4) in order to enable easy coupling, for example by screwing, through the through-opening 307. As an alternative, the coupling could be done by brazing.

In the example described, the upper face of each chip 201 is electrically and/or mechanically coupled to one of the electrical conductors 204a-c, for example at a boss 206 of this conductor 204a-c. Preferably, the upper faces of the chips 201 are coupled at the same time mechanically and electrically to the conductor 204a-c, preferably by brazing.

To attach the module to an electronic circuit board 208 (visible in FIG. 4) of the control device 108, the module 107 moreover has vertical pins 210 for respectively electrically connecting the chips 201 and/or the substrate 202 and/or the conductors 204. These pins 210 have respective connection ends 210′ for connection to the circuit board 208. For example, these connection ends 210′ are inserted in corresponding openings of the circuit board 208 and are fixed to the latter by a press fit or else by welding.

The electrical system 100 moreover preferably has a support 212 on which the module 107 is mounted. This support 212 has, for example, a metal plate and is designed notably to promote dissipation of heat emitted by the module 107. In the example described, the support 212 is common to the three modules 107.

The module 107 moreover has an overmolded block 214, which is electrically insulating, rigid and at least partially encapsulates each chip 201. Preferably, the block 214 completely encapsulates the one or more chips 201 of the module 107. The block 214 comprises, for example, an epoxy resin. It is, for example, produced by the transfer molding technique or by the compression molding technique.

For example, the one or more chips 201 are bare chips embedded in the block 213 so as to produce the encapsulation therefrom. The block 214 advantageously encapsulates other components of the module 107, as will be elucidated below.

The block 214 of each of the modules 107 in this case has a substantially parallelepipedal shape with two substantially parallel opposite large faces 216a, 216b, which are an upper face and lower face, respectively. These large faces 216a, 216b are substantially rectangular, for example.

Preferably, the block 214 encapsulates not only the chips 201 but also at least part of the substrate 202, at least part of the conductors 114 and/or at least part of the pins 210. The rigidity of the block 214 makes it possible to keep the encapsulated elements together mechanically in order to realize their encapsulation.

More specifically, in this case, the block 214 encapsulates the substrate 202 except for a lower face thereof, which is left free to make contact with the support 212. The block 214 also encapsulates the conductors 204a-c, except for their connection ends 204′a-c, and the pins 210, except for their connection ends 210′.

The module 107 moreover comprises projections 218, 220 comprising an electrically insulating material and extending from one face of the block 214.

The block 214 and the projections 218, 220 will be described in more detail with reference to FIGS. 3 and 4.

The faces 216a, 216b are connected by small sides having the longitudinal faces 302a, 302b and transverse faces 310a, 310b. The block 214 is substantially flat, that is to say that a width and a length of the faces 216a, 216b is much greater than a vertical distance separating them.

In the example described, the connection ends 204′a-c of the conductors 204a-c laterally protrude beyond the block 214 by way of its transverse faces 310a, 310b. The connection ends 210′ of the terminals 210 laterally protrude beyond the block 214 by way of its longitudinal faces 302a, 302b.

In the example described, the projections 218, 220 extend vertically upward from the upper face 216a of the block 214. Still in the example described, they are located vertically in line with the substrate 202. These projections 218, 220 have a height, measured from the large upper face 6a, of between 3 mm and 5 cm, for example.

The projections 218, 220 are in this case designed to receive the circuit board 208, in order to support it and keep it at a distance from the face 216a of the block 214 that faces the circuit board 208.

The projections 218, 220 each have, for example, an upper free end defining a contact face 306, which is notably planar, against which the circuit board 208 is designed to rest. Each contact face 306 thus forms a bearing surface or an end stop for the circuit board 208.

However, the projections 218 also have the function of making it possible to fix the circuit board 222. To that end, they have a vertical screw hole 308 leading into the contact face 306. It is thus oriented along a vertical axis of the projection 218. This screw hole 308 is advantageously tapped so as to form a bore for screwing a screw 402, or smooth and intended to interact with a thread-forming or self-tapping screw. Said screws pass, for example, through orifices 404 located in correspondence in the circuit board 208.

In the example described, four fixing projections 218 are provided that are located at corners of the upper face 216a of the block 214.

By contrast, the projection 220 does not have the function of fixing the circuit board 208, but only the function of providing a bearing surface or an end stop for the circuit board 208. It will be referred to as “bearing projection” below. Thus, the bearing projection 220 does not retain the circuit board 208, that is to say that it makes it possible to move the circuit board 208 upward away from the upper face 216a of the block 214. For example, the contact face 306 of the bearing projection 220 does not have a bore.

The bearing projection 220 is located, for example, substantially in a central part of the upper face 216a and preferably equidistantly from the fixing projections 218.

Each projection 218, 220 (and in particular the bearing projection 220) can be configured to damp vibrations of the circuit board 208. The location of each projection provided for damping purposes may also depend on the configuration of the circuit board 208. In general, each projection provided for damping purposes is located at a vibration antinode of the circuit board 208.

To limit vibrations further, stops could also be provided facing each projection provided for damping purposes, on the other side of the circuit board 208.

In general, the module 107 comprises at least one fixing projection, like the projections 218, and/or at least one bearing projection, like the projection 220.

Preferably, the fixing projections 218 and/or bearing projections 220 have substantially the same height.

Each projection may notably have the shape of a cone frustum. This is the case, for example, for the fixing projections 218. As an alternative, each projection may have the shape of a truncated pyramid, notably with a square base. This is the case, for example, for the bearing projections 220.

In a variant, the module 107 could solely comprise one or more fixing projections. In another variant, the module 107 could solely comprise one or more bearing projections.

According to one embodiment, at least one contact face 306 is in direct contact with a lower face of the circuit board 208. In a variant, a filling material is interposed between this contact face 306 and the circuit board 208, such that the circuit board 208 bears against the contact face 306 through the filling material. This filling material is advantageously thermally conductive in order to make it possible for heat to circulate from the circuit board 208 to the block 214 in order to cool the circuit board 208 and/or electronic components (not shown) borne by the latter. For example, the filling material has a thermal conductivity of between 1 and 5 W m⁻¹ K⁻¹.

According to the embodiment of FIGS. 2 to 4, each projection 218, 220 is formed integrally with the block 214. Thus, the block 214 and the one or more projections 218, 220 are formed in one piece. This may be done notably by providing a mold with a main molding cavity corresponding to the block 214 and at least one secondary molding cavity respectively corresponding to the one or more projections. Each projection 218, 220 is thus, for example, made of epoxy resin, like the block 214.

An exemplary method 500 for manufacturing the electrical system having the modules 107, the support 212 and the circuit board 208 will now be described with reference to FIG. 5.

During a step 502, the assembly of chips 201, substrate 202, conductors 204a-c and pins 210 is obtained.

During a step 504, the assembly obtained is overmolded using a mold having a main molding cavity corresponding to the block 214 and shapes corresponding to the projections 218, 220 in communication with the main cavity. Thus, a single part is obtained by the molding, this part having the block 214 and the projections 218, 220. Preferably, the transfer molding technique or else the compression molding technique is used. Step 504 thus provides one of the modules 107. Steps 502, 504 are repeated to obtain the other modules 107.

During a step 506, the modules 107 are fitted against the support 212 and fixed thereto.

During a step 508, a machine tool is used to lower the circuit board 208 toward the upper faces 216a of the modules 107. During this lowering movement, the pins 210 are inserted into the corresponding openings 406 of the circuit board 208 (these openings are visible in FIG. 4). The pins 210 are, for example, press-fitted such that their connection ends 210′ have a larger diameter than the opening 406. Thus, these connection ends 210′ are radially compressed when they are being inserted, this requiring a considerable insertion force on the part of the machine tool.

During a step 510, the circuit board 208 comes into contact with the projections 218, 220, this on the one hand making it possible to control the vertical distance between the circuit board 208 and the modules 107 by avoiding having the machine tool lower the circuit board 208 too far. On the other hand, this contact brings about an increase in the reaction to the movement of the circuit board 208, this being able to be used as a signal to stop the movement.

Thus, during a step 512, the machine tool detects the increase in the reaction to the movement, thereby indicating that a lowering movement for installing the circuit board 208 has gone as far as it can.

In response to detecting the increase in the reaction to the movement, the machine tool stops the movement of the circuit board 208 during a step 514. It is thus possible to avoid exerting too great a force when the circuit board 208 is being installed. The machine tool serving to install the circuit board 208 in this sense advantageously comprises stops intended to face the one or more bearing projections 220, on the other side of the circuit board 208.

Another exemplary module 601 according to the invention will now be described.

With reference to FIGS. 6 to 8, this module 601 is similar to the module 107 of the preceding figures, except that it has at least one projection, denoted by the reference 602, which is a different part of the block 214.

In the example described, the one or more projections 602 replace the fixing projections 218 with retention of their bearing and fixing functions. However, this variant could apply equally well to the bearing projections 220.

As is more particularly apparent from FIGS. 7 and 8, the projection 602 is preferably fixed to one of the conductors 204a-c of the module 107. In the example described, it is located on a planar part 702 of the conductor 204c. Of course, the projection 602 could be fixed to one of the other conductors 204a, 204b. The projection 602 extends from an upper face 704 of the planar part 702, opposite a lower face 706 that faces the substrate 12. The projection 602 in this instance is positioned close to an edge 708 of the substrate 202 and/or one of the connection ends 204′a-c of the conductor 204a-c.

With reference to FIG. 8, in order to fix the projection 602 in place, the conductor 204a-c advantageously has an aperture 802 through which the projection 602 is fixed in place by a fixing element 804, notably by hot rivet-heading or riveting. A lower face of the projection 602 is thus kept bearing against the upper face 704 of the planar part 702 of the conductor 204c, the fixing element 804 bearing against the opposite lower face 706 by passing through the aperture 802. Any other way of fixing in place is possible, of course.

The projection 602 may be produced by a first overmolding of the conductor 204c, either directly in its form illustrated in the figures or else with subsequent riveting or rivet-heading of the fixing element 804 in order to give it its illustrated form. The block 214 is then produced, for example, after this first overmolding and, where appropriate, the riveting or rivet-heading operation.

The block 214 encapsulates a base 806 of the projection 602. In other words, the block 214 is overmolded on the base 806. For example, the block 214 encapsulates the projection 602 over a height of several tenths of millimeters, for example between 0.2 and 1.5 mm, from the upper face 704 of the planar part 702 of the conductor 204c. It will be appreciated that the projection 602 has inclined lateral walls, this enabling the block 214 to cover them vertically and thus improve the fixing of the projection 602 in place.

An advantage of using two separate parts for the projection 602 and the block 214 is to avoid the propagation of cracks between the projection 602 and the block 214.

The projection 602 may be made of the same material as the block 214, notably of epoxy resin.

In a variant, a different material is used. This has the advantage notably of making it possible to use a material suitable for producing a thread intended for more standard screws and/or damping vibrations.

It should also be noted that the invention is not limited to the embodiments described above. Indeed, it will become apparent to a person skilled in the art that various modifications can be made to the embodiments described above, in the light of the teaching that has just been disclosed to them.

In particular, the projections 218, 220, 602 could have different shapes, other than frustoconical or truncated pyramid. They could furthermore have different heights.

Moreover, each chip may have a different type of component than a semiconductor switch, for example: a passive electronic component, such as an electrical resistor and/or a capacitive component, and/or a semiconductor chip for performing one or more logic functions in order to enable the power electronics module to format power electronics signals.

Moreover, the projections 218, 220, 602 may be designed to interact with any component other than an electronic circuit board, like the circuit board 208, notably a framework for fixing the module. Thus, by virtue of the projections 218, 220, 602, any component (the circuit board 208 or any other component) is positioned at a distance from the face 216a of the block 214 without having to use additional parts.

Moreover, the system could be used in an air compressor. Thus, the rotary electric machine 104 could be provided to drive an air compression element, notably in order to generate a flow of charge air for a motor.

In the detailed presentation of the invention set out above, the terms that are used must not be understood as limiting the invention to the embodiments disclosed in the present description, but must be understood as including all equivalents, the anticipation of which is within the scope of a person skilled in the art applying their general knowledge to the implementation of the teaching that has just been disclosed to them.

1. A power electronics module having:
at least one electronic chip; and
an electrically insulating overmolded block at least partially encapsulating each chip;
wherein it comprises at least one projection against which a component can bear, such as an electronic circuit board for controlling each chip, the projection comprising an electrically insulating material and extending from one face of the block.

2. The module as claimed in claim 1, the projection having a free end defining a contact face of the component.

3. The module as claimed in claim 1, the contact face being planar.

4. The module as claimed in claim 1, at least one projection being designed to fix the component in place.

5. The module as claimed in claim 2, the contact face of the projection designed to fix the component in place having a screw hole.

6. The module as claimed in claim 5, the screw hole being either tapped, or smooth and intended to interact with a thread-forming or self-tapping screw.

7. The module (as claimed in claim 2, the contact face of the projection being designed to allow the component to move away from this contact face.

8. The module as claimed in claim 7, the contact face of the projection designed to allow the component to move away does not have a bore.

9. The module as claimed in claim 1, the projection having the shape of a cone frustum and/or a truncated pyramid.

10. The module as claimed in claim 1, the projection and the block being formed in one piece.

11. The module as claimed in claim 1, the projection and the block being formed in two separate parts.

12. The module as claimed in claim 11, comprising an electrical conductor, and the projection being fixed to the conductor.

13. The module as claimed in claim 12, the conductor having an aperture, and the projection being fixed to the conductor through the aperture.

14. The module as claimed in claim 13, the projection being fixed to the conductor by riveting or rivet-heading or overmolding.

15. The module as claimed in claim 11, the block encapsulating a base of the projection.

16. An electrical system having a module as claimed in claim 1 and a component bearing against each projection.

17. A method for manufacturing a module as claimed in claim 1, having the following steps:
obtaining the one or more chips;
overmolding the block over the chips, for example by transfer molding or by compression molding; and
producing each projection against which the component can bear.

18. The method as claimed in claim 17, the overmolding step being performed by using a mold having a main molding cavity corresponding to the block and at least one secondary molding cavity respectively corresponding to the one or more projections, this secondary cavity being in communication with the main cavity, such that each projection and the block are in one piece.

19. The method as claimed in claim 17, the production of each projection being separate from the overmolding step, such that the one or more projections and the block are separate parts.

20. A method for manufacturing an electrical system as claimed in claim 16, having the following steps:
manufacturing a module by:
obtaining the one or more chips;
overmolding the block over the chips, for example by transfer molding or by compression molding; and
producing each projection against which the component can bear;
using a machine tool to move the component towards the face of the block until the component bears against each projection;
using the machine tool to detect an increase in a reaction to the movement; and
using the machine tool to stop the movement of the component.
